(19) United States
(12) Patent Application Publication
(10) Pub. No.: US 2010/0289683 A1
(43) Pub. Date: Nov. 18, 2010

(54) REFERENCE VOLTAGE GENERATION CIRCUIT, A/D CONVERTER AND D/A CONVERTER

(75) Inventor: Takayasu KITO, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/781,304

(22) Filed: May 17, 2010

(30) Foreign Application Priority Data
May 18, 2009 (JP) 2009-120135

(51) Int. Cl. H03M 1/66; G05F 3/16; H03M 1/34

(52) U.S. Cl. 341/144; 323/313; 341/158

(57) ABSTRACT

A reference voltage generation circuit of the present invention includes: a reference voltage generation part 12 that is connected between a first reference voltage terminal VRT and a second reference voltage terminal VRB and that generates a plurality of reference voltages when being supplied with a power supply current from the first and second reference voltage terminals; capacitors 13a, 13b for storing charge that are connected to the first and second reference voltage terminals, respectively; a reference voltage detection circuit 16 that detects voltage values at the first and second reference voltage terminals; current control circuits 11a, 11b that control a magnitude of a power supply current that is allowed to flow through the reference voltage generation part so that the first and second reference voltage terminals are kept at predetermined voltage values, in accordance with the voltage values detected by the reference voltage detection circuit; and switching parts 14a to 14d that switch the connection between the first and second reference voltage terminals so as to replace the reference voltage generation part with a high-resistance element 15. During a power-saving mode, the reference voltage generation part is switched to the high-resistance element, whereby a current flowing between the first and second reference voltage terminals is reduced, and the potentials of the capacitors are kept due to a minute current. Therefore, a recovery time from the power-saving mode becomes short.

### BACKGROUND OF THE INVENTION

1. Field of the Invention

The present invention relates to a reference voltage generation circuit that generates a plurality of reference voltages by resistance voltage division from two reference voltages generated with a power supply current. The present invention also relates to an A/D converter that generates a digital signal by quantizing an input analog signal based on a plurality of reference voltages, and a D/A converter that generates an analog signal from an input digital signal.

2. Description of Related Art

As digitization proceeds in an AV field, an information communication field, and the like, there is an increasing demand for high speed and high precision in an A/D converter and a D/A converter that are key devices, and at the same time, there also is a demand for lower power consumption that contradicts the performance.

Examples of the A/D converter widely used in the AV field, the information communication field, and the like include a flash type A/D converter, a pipeline type A/D converter, a sequential comparison type A/D converter; and examples of the D/A converter include a resistance string type D/A converter and an R-2R type D/A converter. The converters convert data using predetermined reference voltages. As the predetermined reference voltages, a plurality of reference voltages are used, which are generated by voltage division with resistors corresponding to required voltages connected in series between two reference voltages output from a circuit that generates reference voltages to be supplied to an internal circuit.

For two reference voltages generated by a reference voltage generation circuit, a configuration in which a large external capacitor is provided is adopted in order to ensure the stability with respect to an internal circuit of a large circuit scale and reduce the consumption current (see, for example, JP 2008-42815 A). In the case where such a large external capacitor is provided, it takes a long period of time for the capacitor to be charged. A representative example will be described with reference to a reference voltage generation circuit used in a pipeline type A/D converter.

FIG. 3 is a block diagram showing a configuration of a basic pipeline type A/D converter. The pipeline type A/D converter includes n stages that are cascaded (i.e., a first stage 1[1] to an n-th stage 1[n]), a flash A/D converter 2 in a final stage, and a reference voltage generation circuit 3 that generates a plurality of reference voltages. The reference voltage generation circuit 3 generates reference voltages VRT, VRB, VR3, VR5, and VCM.

An input analog signal Vin is converted into a digital signal one bit at a time from a high-order bit to a low-order bit in the n stages. An obtained signal is combined with an output digital signal of the flash A/D converter 2, whereby an output signal is obtained in which the input analog signal Vin is A/D converted by the desired number of bits.

FIG. 3 shows a configuration of only the first stage 1[1] specifically. The configuration of each of the other stages also is the same. More specifically, each stage includes an A/D conversion part 4, a D/A conversion part 5, and a redundant operation part 6.

The A/D conversion part 4 generates and outputs a ternary-coded digital signal from an input analog signal supplied to the instant stage. The digital signal to be output also is supplied to the D/A conversion part 5. The D/A conversion part 5 converts the digital signal output from the A/D conversion part 4 into an analog (voltage) signal using the reference voltages VRT, VRB and supplies the analog signal to the redundant operation part 6. The redundant operation part 6 performs subtraction and amplification with respect to the input analog signal supplied to the instant stage and one analog signal output by the D/A conversion part 5, thereby generating a redundant analog signal. The output signal of the redundant operation part 8 is supplied to a next stage as an input analog signal.

FIG. 4 shows a specific exemplary configuration of the A/D conversion part 4. The A/D conversion part 4 includes comparators 7a, 7b that compare the input analog signal Vin with the reference voltages VR3, VR5, respectively, and an encoder 8 that encodes the comparison results of the comparators 7a, 7b to output a digital signal. The output of the encoder 8 becomes a digital output value for the instant stage.

FIG. 5 shows a specific configuration of the D/A conversion part 5. The D/A conversion part 5 includes a logic operation part 9 and a voltage supply part 10. The voltage supply part 10 selects and supplies the reference voltages VRT, VRB, VCM obtained from the reference voltage generation circuit 3 in accordance with the output of the logic operation part 9. The logic operation part 9 outputs a signal that controls the selection of the reference voltages by the voltage supply part 10 in accordance with the ternarized digital signal supplied from the A/D conversion part 4.

FIG. 6 shows a specific exemplary configuration of the reference voltage generation circuit 3 included in the circuit shown in FIG. 3. The reference voltage generation circuit 3 includes a reference voltage generation part 12 and current bias sources 11a, 11b that are connected to both ends of the reference voltage generating part 12 so as to allow a constant current to flow.

The reference voltage generation part 12 includes eight voltage-dividing resistors 12a to 12h having an equal resistance value. The current bias source 11a is composed of a p-channel type MOS transistor (hereinafter, referred to as a “PMOS”) whose gate is controlled with a bias voltage (biasp) and is connected in series between a power supply terminal VDD and a reference voltage terminal VRT. In the following description, for convenience, the voltage of the reference voltage terminal VRT will be described as a reference voltage VRT. The other terminals and the terminal voltages thereof will be described using the same symbol. The current bias source 11b is composed of an N-channel type MOS transistor (hereinafter, referred to as an “NMOS”) whose gate is controlled with a bias voltage (biasn) and is connected in series between a ground terminal VSS and a reference voltage terminal VRB.

The eight voltage-dividing resistors 12a to 12h are connected in series between the two reference voltage terminals VRT, VRB. A reference voltage terminal VR3 is connected to between the voltage-diving resistors 12c and 12d; a reference voltage terminal VCM is connected to between the voltage-dividing resistors 12d and 12e; and a reference voltage terminal VR5 is connected to between the voltage-dividing resistors 12e and 12f, respectively.

The reference voltage terminals VRT, VRB are connected to pads VRT_PAD and VRB_PAD outside a chip, respectively, and the pads VRT_PAD and VRB_PAD are connected to the ground terminals VSS via external capacitors 13a, 13b.

The terminal voltages VRT, VRB determine an input range of the pipeline type ADC, and the reference voltage VCM is used as a common mode voltage of the ADC. The reference voltages VR3, VR5 are used as reference voltages for comparison of the comparators 7a, 7b in the A/D conversion part 4.

### SUMMARY OF THE INVENTION

As means for reducing the power consumption of the A/D converter or the D/A converter, apart from the method for suppressing power consumption during an operation by changing a circuit configuration or the like, there is a method for reducing power by stopping the supply of a current to a circuit or reducing a current to be supplied, when not using the A/D converter or the D/A converter (see, for example, JP 11(1999)-234061 A). These methods lead to the large reduction in power when the A/D converter or the D/A converter is applied to equipment that is not in continuous use at all times.

However, with the reference voltage generation circuit 3 shown in FIG. 6 mounted on a conventional pipeline type ADC, since the external capacitors 13a, 13b are provided, it takes a considerable amount of time for the voltages at the terminals VRT, VRB, which determine the input range of the ADC, to reach desired levels. This increases a time taken for the A/D conversion operation to become stable from the cancellation of the power-saving mode. Thus, there is a problem that, only when the time for activation can be ensured sufficiently, is the suppression of power consumption allowable.

An object of the present invention is to provide a reference voltage generation circuit in which a transition time to a power-saving mode and a recovery time are short and an intermittent operation in a short period of time can be performed. Another object of the present invention is to provide an A/D converter and a D/A converter using the reference voltage generation circuit.

A reference voltage generation circuit of the present invention includes: a reference voltage generation part that is connected between a first reference voltage terminal and a second reference voltage terminal and that generates a plurality of reference voltages when being supplied with a power supply current from the first and second reference voltage terminals; capacitors for storing charge that are connected to the first and second reference voltage terminals, respectively; a reference voltage detection circuit that detects voltage values at the first and second reference voltage terminals; a current control circuit that controls a magnitude of a power supply current that is allowed to flow through the reference voltage generation part so that the first and second reference voltage terminals are kept at predetermined voltage values, in accordance with the voltage values detected by the reference voltage detection circuit; and a switching part that switches the connection between the first and second voltage terminals so as to replace the reference voltage generation part with a high-resistance element during a power-saving mode.

In the reference voltage generation circuit with this configuration, a flowing current can be reduced by raising the resistance between the first reference voltage terminal and the second reference voltage terminal during the power-saving mode. Further, the voltage of the capacitor for storing charge between the first reference voltage terminal and the second reference voltage terminal is held by the current control circuit. Therefore, a recovery time from the power-saving mode is short, an intermittent operation in a short period of time can be performed, and the power-saving mode for reducing power consumption can be used frequently.

### BRIEF DESCRIPTION OF THE DRAWINGS

FIG. 1 is a circuit diagram showing a reference voltage generation circuit in Embodiment 1 of the present invention.

FIG. 2 is a circuit diagram showing a reference voltage generation circuit in Embodiment 2 of the present invention.

FIG. 3 is a block diagram showing a basic configuration of a pipeline type A/D converter in a conventional example.

FIG. 4 is a diagram showing an A/D conversion part of the pipeline type A/D converter.

FIG. 5 is a diagram showing a D/A conversion part of the pipeline type A/D converter.

FIG. 6 is a circuit diagram showing a reference voltage generation circuit in a conventional example.

### DETAILED DESCRIPTION OF THE INVENTION

The reference voltage generation circuit of the present invention can assume the following embodiments based on the above configuration.

More specifically, the switching part may include a reference voltage generation part switch that is connected between at least one of the first, and second reference voltage terminals and the reference voltage generation part, and a high-resistance connection switch that is connected between the first and second reference voltage elements via the high-resistance element. During a normal mode, the reference voltage generation part switch is controlled to connect the reference voltage generation part between the first and second reference voltage terminals to supply the power supply current, and the high-resistance connection switch is controlled to separate the high-resistance element from between the first and second reference voltage terminals, and during the power-saving mode, the reference voltage generation part switch is controlled to interrupt the power supply current, and the high-resistance connection switch is controlled to connect the high-resistance element between the first and second reference voltage terminals.

Further, the switching part may include a variable resistance switch connected between at least one of the first and second reference voltage terminals and the reference voltage generation part, and during the power-saving mode, the variable resistance switch is controlled so as to increase a resistance value thereof more than that during a normal mode.

Further, the reference voltage detection circuit may be composed of a reference voltage part that outputs a predetermined reference voltage and a comparator that compares the voltage values of the first and second reference voltage terminals with the predetermined reference voltage output by the reference voltage part.

An A/D converter may be configured, which includes the reference voltage generation circuit with any of the above configurations, and an A/D conversion part that converts an analog signal into a digital signal based on the plurality of reference voltages output from the reference voltage generation circuit.

Further, a D/A converter may be configured, which includes the reference voltage generation circuit with any of the above configurations, and a D/A conversion part that converts a digital signal into an analog signal based on the plurality of reference voltages output from the reference voltage generation circuit.

The disclosure of Japanese Patent Application 2009-120135 filed on May 18, 2009, including the specification, drawings and claims, is incorporated herein by reference in its entirety.

Hereinafter, the present invention will be described more specifically by way of embodiments with reference to the drawings.

### Embodiment 1

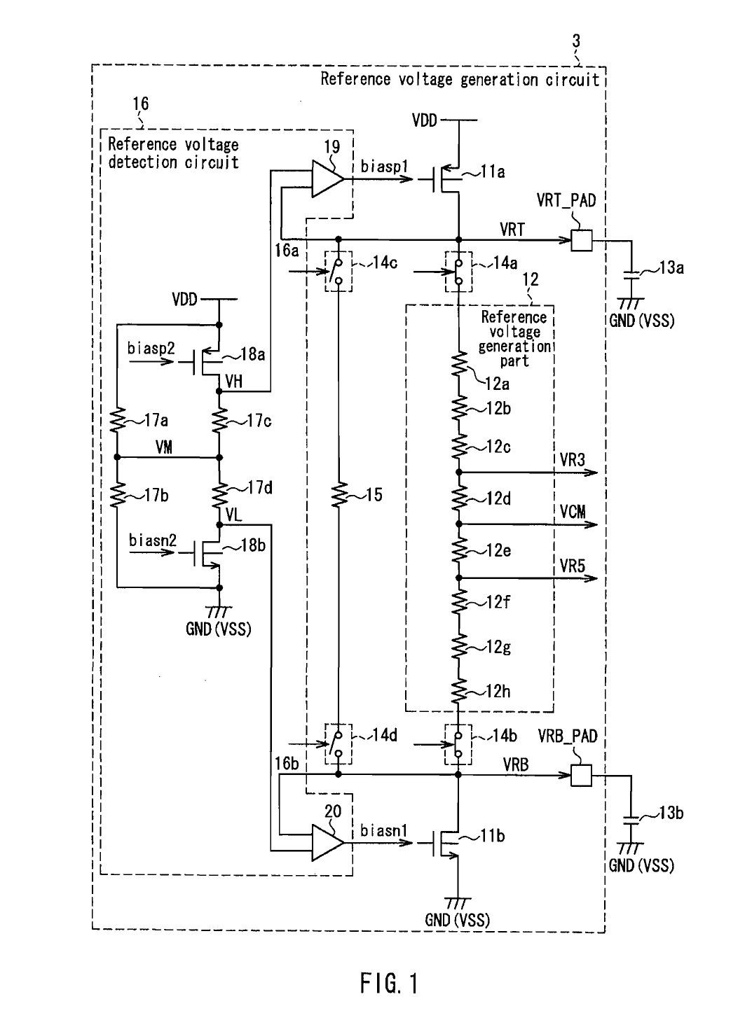

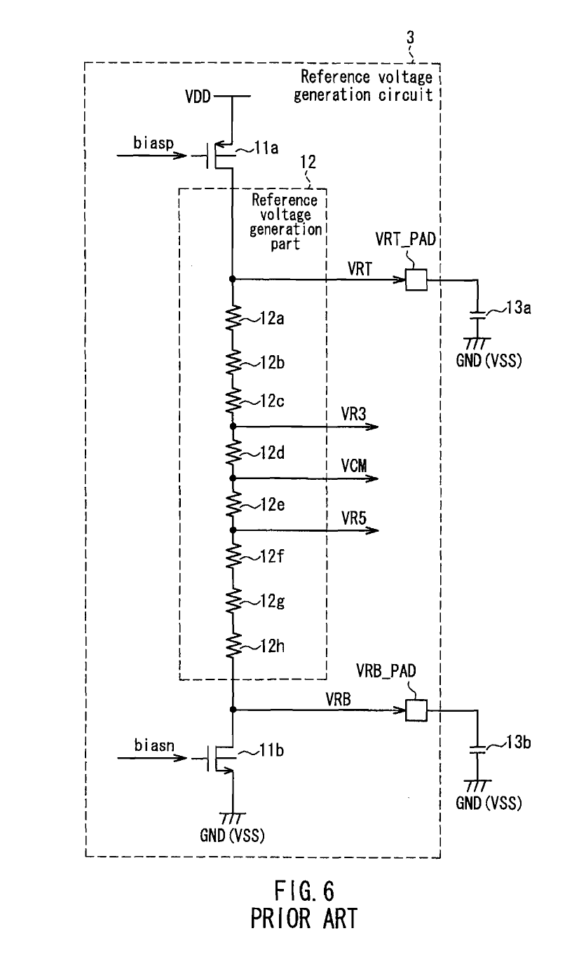

FIG. 1 is a circuit diagram showing a reference voltage generation circuit in Embodiment 1 of the present invention. The case where this circuit is used as a reference voltage generation circuit for a pipeline type ADC will be exemplified. The same elements as those in the circuit in the conventional example shown in FIG. 6 are denoted with the same reference numerals as those therein.

The reference voltage generation circuit includes a reference voltage generation part 12 and current bias sources 11a and 11b that allow a constant current to flow. Thus, a circuit similar to the reference voltage generation circuit shown in FIG. 6 is configured. Further, as the feature of the present embodiment, a reference voltage detection circuit 16 for controlling the current bias sources 11a and 11b is provided.

The reference voltage generation part 12 includes eight voltage-dividing resistors 12a to 12h having an equal resistance value. The current bias source 11a has a P-channel type MOS transistor (hereinafter, referred to as a “PMOS”) whose gate is controlled with a bias voltage (biasp1) and is connected in series between a power supply terminal VDD and a (first) reference voltage terminal VRT. The current bias source 11b has an N-channel type MOS transistor (hereinafter, referred to as an “NMOS”) whose gate is controlled with a bias voltage biasn1 and is connected in series between a ground terminal VSS and a (second) reference voltage terminal VRB. The voltages of the reference voltage terminals VRT, VRB are described as reference voltages VRT, VRB, respectively, using the same symbols.

The eight voltage-dividing resistors 12a to 12h are connected in series between the two reference voltage terminals VRT, VRB. The voltage-dividing resistor 12a is connected to the reference voltage terminal VRT via an analog SW (switch) 14a, and the voltage-dividing resistor 12h is connected to the reference voltage terminal VRB via an analog SW 14b. A reference voltage terminal VR3 is connected to between the voltage-dividing resistors 12c, 12d; a reference voltage terminal VCM is connected to between the voltage-dividing resistors 12d, 12e; and a reference voltage terminal VR5 is connected to between the voltage-dividing resistors 12e, 12f, respectively.

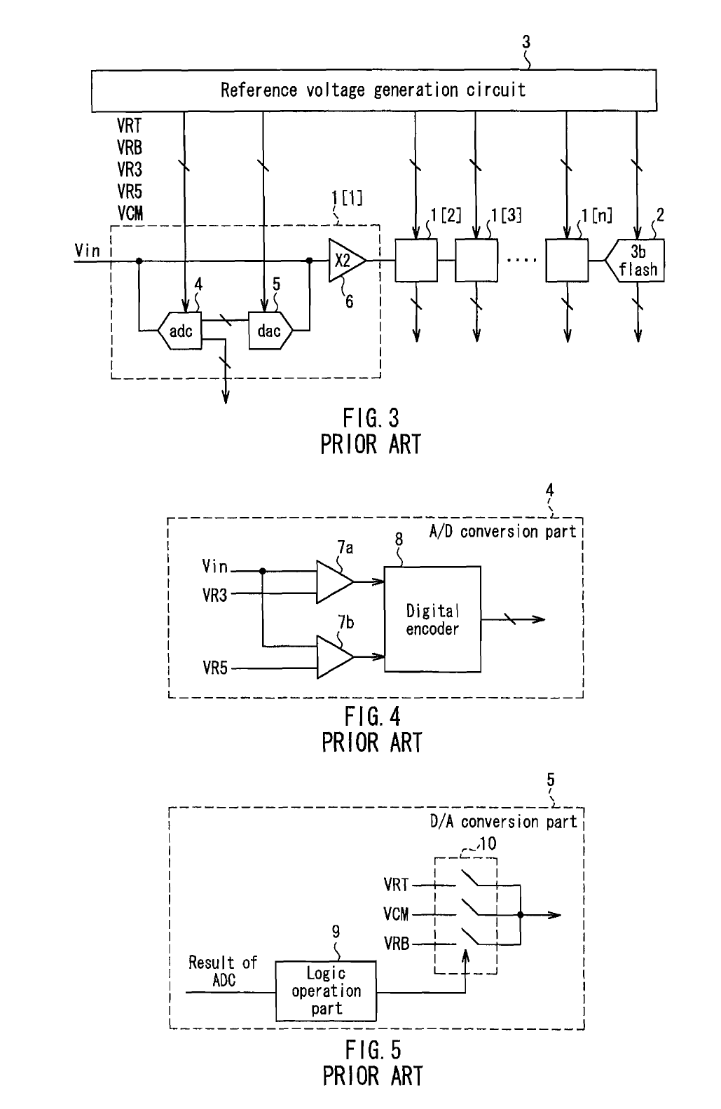

The reference voltage terminals VRT, VRB are connected to pads VRT_PAD and VRB_PAD outside of a chip, respectively. The pads VRT_PAD and VRB_PAD are connected to the ground terminals VSS via external capacitors 13a, 13b, respectively. The terminal voltages VRT, VRB determine an input range of a pipeline type ADC, and the reference voltage VCM is used as a common mode voltage of the ADC. The reference voltages VR3, VR5 are used as reference voltages for comparison of the comparators 7a, 7b in the A/D conversion part 4 that is a constituent element of the pipeline type ADC shown in FIG. 3.

The analog SWs 14a, 14b have a low resistance in an ON state during a normal mode and is controlled to be in an OFF state during a power-saving mode to interrupt the supply of a current to the voltage-dividing resistors 12a to 12h. Further, one end of an analog SW 14c is connected to the reference voltage terminal VRT, and the other end thereof is connected to one end of a high resistance resistor 15. On the other hand, one end of an analog SW 14d is connected to the reference voltage terminal VRB, and the other end thereof is connected to the other end of the high resistance resistor 15. The analog SWs 14c, 14d are in an OFF state during a normal mode, and is controlled to be in an ON state during the power-saving mode to supply a current to the high resistance resistor 15.

The reference voltage detection circuit 16 includes a series circuit of the resistors 17a and 17b connected in series between a power source VDD and a ground VSS, a series circuit of a current bias source 18a, resistors 17c, 17d, and a current bias source 18b connected in series between the power source VDD and the ground VSS, and comparators 19, 20. The current bias source 18a is a constant current source composed of a PMOS, and the current bias source 18b is a constant current source composed of an NMOS.

A first input terminal 16a of the reference voltage detection circuit 16 is connected to the reference voltage terminal VRT and used as one input of the comparator 19. A second input terminal 16b of the reference voltage detection circuit 16 is connected to the reference voltage terminal VRB and used as one input of the comparator 20.

The resistors 17a and 17b have the same resistance value, and a voltage of VDD/2 is output from a VM terminal that is a node between the resistors 17a and 17b. The node between the resistors 17c, 17d is connected to the VM terminal, and a VH terminal at the other end of the resistor 17c is connected to the VDD via the current bias source 18a. A gate voltage (biasp2) of the current bias source 18a is set so that the voltage at both ends of the resistor 17c becomes a half of a desired voltage between the reference voltages VRT and VRB.

The comparator 19 compares the voltage at the VH terminal with the reference voltage VRT. In the case where the reference voltage VRT is lower, the comparator 19 lowers the potential of the gate bias voltage (biasp1) of the current bias source 11a that is a current control circuit to increase a current flowing through the voltage-dividing resistors 12a to 12h. In the case where the reference voltage VRT is high, a current flowing through the voltage-dividing resistors 12a to 12h is reduced by raising the potential of the gate bias voltage (biasp 1) of the current bias source 11a.

On the other hand, the VL terminal at the other end of the resistor 17d is connected to the VSS via the current bias source 18b. The gate voltage biasn2 of the current bias source 18b is set so that the voltage at both ends of the resistor 17d becomes a half of a desired voltage between the reference voltages VRT and VRB.

The comparator 20 compares the voltage at the VL terminal with the reference voltage VRB. In the case where the reference voltage VRB is lower, the comparator 20 lowers the potential of the gate bias voltage biasn1 of the current bias source 11b that is a current control circuit to decrease a current flowing through the voltage-dividing resistors 12a to 12h. In the case where the reference voltage VRB is higher, the comparator 20 raises the potential of the gate bias voltage biasn1 of the current bias source 11b to increase a current flowing from the voltage-dividing resistors 12a to 12h.

Due to the feedback operation of the reference voltage detection circuit 16 as described above, the desired voltages at the VH and VL terminals, which are separated from a load circuit and stable, becomes equal to the reference voltages VRT, VRB, and the potential difference between the reference voltages VRT, VRB and the midpoint voltage of the reference voltages VRT, VRB becomes a desired voltage.

During the power-saving mode, the supply of a current with respect to the voltage-dividing resistors 12a to 12h is interrupted by the analog SWs 14a to 14d, and the high resistance resistor 15 is connected between the reference voltage terminals VRT and VRB. In this state, the reference voltage terminals VRT, VRB are retained at desired voltages by the reference voltage detection circuit 16. However, a current flowing through the current bias sources 11a, 11b is reduced remarkably, so that power is reduced.

Further, due to a minute current flowing through the current bias sources 11a, 11b, the voltages at the capacitors 13a, 13b for storing charge are held, which makes a charge/discharge time of the capacitor for storing charge unnecessary. Thus, it does not substantially take a time for shifting to the power-saving mode and a time for recovering. Therefore, the transition time to the power-saving mode and the recovery time from the power-saving mode are short, and an intermittent operation in a short period of time can be performed. Consequently, the power-saving mode for reducing power consumption can be used more frequently compared with the conventional example.

### Embodiment 2

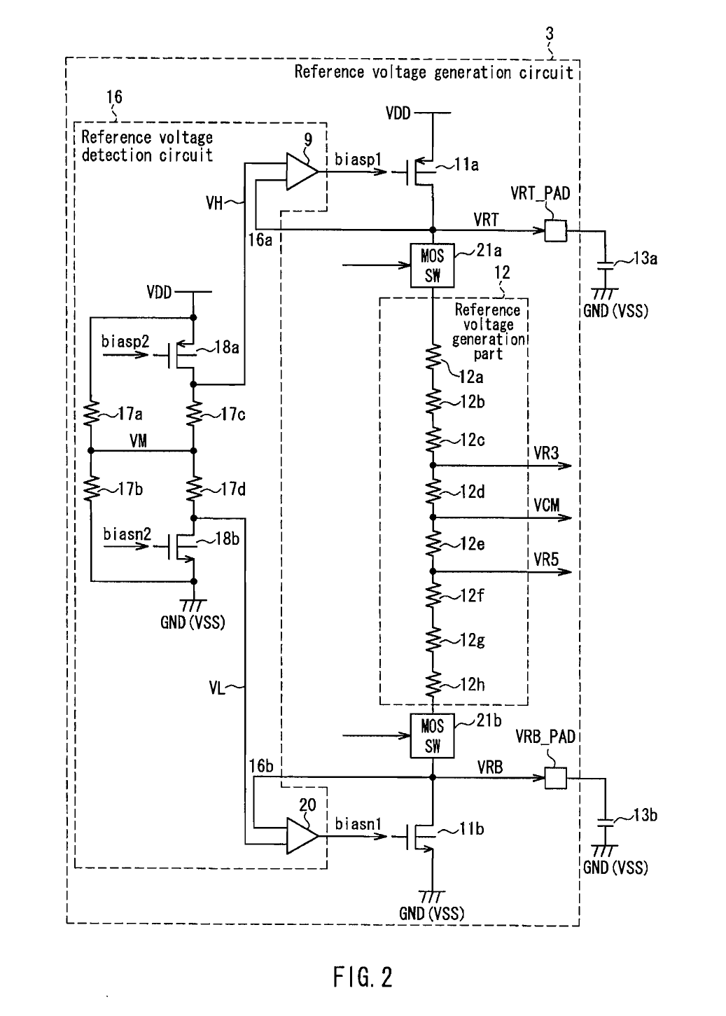

FIG. 2 is a circuit diagram showing a reference voltage generation circuit in Embodiment 2 of the present invention. In this circuit, the same elements as those in the circuit of Embodiment 1 shown in FIG. 1 are denoted with the same reference numerals as those therein.

In the reference voltage generation circuit of the present embodiment, a MOS SW 21a is connected between the reference voltage terminal VRT and the voltage-dividing resistor 12a and a MOS SW 21b is connected between the reference voltage terminal VRB and the voltage-dividing resistor 12h in place of the analog SWs 14a to 14d and the high resistance resistor 15 in Embodiment 1. The MOS SWs 21a, 21b are in an ON state during a normal mode, and supply a current to the voltage-dividing resistors 12a to 12h at a low resistance value.

The MOS SW is capable of changing a resistance value by controlling a gate voltage. Therefore, during a power-saving mode, the resistance values of the MOS SWs 21a, 21b can be increased by controlling the gate voltages of the MOS SWs 21a, 21b. Thus, during the power-saving mode, the resistance value between the reference voltage terminals VRT and VRB is increased by the MOS SWs 21a, 21b.

During the power-saving mode, the voltages at the reference voltage terminals VRT, VRB also are retained at desired voltages by the reference voltage detection circuit 16. However, since the resistance value between the reference voltage terminals VRT and VRB is increased, a current caused to flow by the current bias sources 11a, 11b is reduced remarkably, whereby power is reduced.

Further, due to a minute current caused to flow by the current bias sources 11a, 11b, the voltages at the capacitors 13a, 13b for storing charge are held, which makes a charge/discharge time of the capacitor for storing charge unnecessary. Thus, it does not substantially take a time for shifting to the power-saving mode and a time for recovering. Therefore, the transition time to the power-saving mode and the recovery time from the power-saving mode are short, and an intermittent operation in a short period of time can be performed. Consequently, the power-saving mode for reducing power consumption can be used more frequently compared with the conventional example.

In the above embodiment, the reference voltage generation circuit for a pipeline type A/D converter is exemplified. However, the present invention is applicable to the other A/D converter and D/A converter by replacing the voltage-dividing resistors 12a to 12h by voltage-dividing resistors for obtaining desired reference voltages.

As described above, the reference voltage generation circuit of the present invention has a short recovery time from the power-saving mode and hence, can use the power-saving mode for reducing power consumption frequently. Therefore, the present invention is useful for the A/D converter and the D/A converter used in the AV field for a CCD camera, information communication field, etc.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A reference voltage generation circuit, comprising;
a reference voltage generation part that is connected between a first reference voltage terminal and a second reference voltage terminal and that generates a plurality of reference voltages when being supplied with a power supply current from the first and second reference voltage terminals;
capacitors for storing charge that are connected to the first and second reference voltage terminals, respectively;
a reference voltage detection circuit that detects voltage values at the first and second reference voltage terminals;
a current control circuit that controls a magnitude of a power supply current that is allowed to flow through the reference voltage generation part so that the first and second reference voltage terminals are kept at predetermined voltage values, in accordance with the voltage values detected by the reference voltage detection circuit; and
a switching part that switches the connection between the first and second voltage reference terminals so as to replace the reference voltage generation part with a high-resistance element during a power-saving mode.

2. The reference voltage generation circuit according to claim 1, wherein the switching part comprises a reference voltage generation part switch that is connected between at least one of the first, and second reference voltage terminals and the reference voltage generation part, and a high-resistance connection switch that is connected between the first and second reference voltage elements via the high-resistance element,
during a normal mode, the reference voltage generation part switch is controlled to connect the reference voltage generation part between the first and second reference voltage terminals to supply the power supply current, and the high-resistance connection switch is controlled to separate the high-resistance element from between the first and second reference voltage terminals, and
during the power-saving mode, the reference voltage generation part switch is controlled to interrupt the power supply current, and the high-resistance connection switch is controlled to connect the high-resistance element between the first and second reference voltage terminals.

3. The reference voltage generation circuit according to claim 1, wherein the switching part includes a variable resistance switch connected between at least one of the first and second reference voltage terminals and the reference voltage generation part, and during the power-saving mode, the variable resistance switch is controlled so as to increase resistance value thereof more than that during a normal mode.

4. The reference voltage generation circuit according to claim 1, wherein the reference voltage detection circuit is composed of a reference voltage part that outputs a predetermined reference voltage and a comparator that compares the voltage values of the first and second reference voltage terminals with the predetermined reference voltage output by the reference voltage part.

5. An A/D converter comprising the reference voltage generation circuit according to claim 1, and an A/D conversion part that converts an analog signal into a digital signal based on the plurality of reference voltages output from the reference voltage generation circuit.

6. A D/A converter comprising the reference voltage generation circuit according to claim 1, and a D/A conversion part that converts a digital signal into an analog signal based on the plurality of reference voltages output from the reference voltage generation circuit.
